(19) United States
(12) Patent Application Publication
(10) Pub. No.: US 2021/0255531 A1
(43) Pub. Date: Aug. 19, 2021

(54) HEAT DISSIPATION STRUCTURE AND PROJECTION DEVICE

(71) Applicant: Coretronic Corporation, Hsin-Chu (TW)

(72) Inventors: Chih-Sheng Wu, Hsin-Chu (TW); Kai-Lun Hou, Hsin-Chu (TW)

(73) Assignee: Coretronic Corporation, Hsin-Chu (TW)

(21) Appl. No.: 17/163,534

(22) Filed: Jan. 31, 2021

(30) Foreign Application Priority Data
Feb. 18, 2020 (CN) 202020178906.3

(51) Int. Cl. G03B 21/16; H05K 7/20

(52) U.S. Cl. CPC G03B 21/16; H05K 7/2039; H05K 7/20136

(57) ABSTRACT

A heat dissipation structure including at least one heat dissipation fin set and at least one heat pipe is provided. The heat dissipation fin set includes at least two heat dissipation fins, each having a side edge and a positioning groove located at the side edge. The side edge of one heat dissipation fin is joined to the side edge of another heat dissipation fin. The positioning groove of one heat dissipation fin is aligned with the positioning groove of another heat dissipation fin to form a positioning perforation. The heat pipe is clamped between the heat dissipation fins and passes through the positioning perforation along an extension axis. On a cross section perpendicular to the extension axis, a cross-sectional width and a cross-sectional thickness of the heat pipe are respectively D1 and D2, where D1 is greater than or equal to D2. A projection device is also provided.

### CROSS-REFERENCE TO RELATED APPLICATION

This application claims the priority benefit of China application serial no. 202020178906.3, filed on Feb. 18, 2020. The entirety of the above-mentioned patent application is hereby incorporated by reference herein and made a part of this specification.

### BACKGROUND

### Technical Field

The disclosure relates to a heat dissipation structure and a projection device, and particularly to a heat dissipation structure and a projection device to which the heat dissipation structure is applied.

### Description of Related Art

Conventional heat dissipation structures may include heat pipes and heat dissipation fins, wherein the heat dissipation fins are provided with perforations for installation of the heat pipes. Specifically, the heat pipe passes through the perforation and is fixed to the heat dissipation fin by a welding process. For example, a solder may be coated on the heat pipe first, and then the heat pipe is passed through the perforation, such that the heat pipe is fixed to an inner wall surface of the perforation through the solder. Alternatively, the heat pipe may pass through the perforation first, and then the solder is filled between the heat pipe and the inner wall surface of the perforation, such that the heat pipe is fixed to the inner wall surface of the perforation of the heat dissipation fins through the solder. In order to ensure a sufficient amount of the solder between the heat pipe and the inner wall surface of the perforation, and to ensure the integrity of distribution of the solder, most conventional heat dissipation fins are provided with grooves communicated with the perforations and configured to accommodate the solder or fill the solder via the grooves. However, the design of the grooves would reduce the contact area between the heat pipe and the heat dissipation fin, thereby affecting the heat dissipation efficiency.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure provides a heat dissipation structure and a projection device, which have a good heat dissipation efficiency.

Other objectives and advantages of the invention can be further understood from the technical features disclosed by the disclosure.

In order to achieve one, part, or all of the above objectives or other objectives, an embodiment of the disclosure provides a heat dissipation structure, which includes at least one heat dissipation fin set and at least one heat pipe. The heat dissipation fin set includes at least two heat dissipation fins, wherein each heat dissipation fin has a side edge and a positioning groove located at the side edge. The side edge of one of the at least two heat dissipation fins is joined to the side edge of another one of the at least two heat dissipation fins, and the positioning groove of one of the at least two heat dissipation fins is aligned with the positioning groove of another one of the at least two heat dissipation fins to form a positioning perforation. The heat pipe is clamped between the at least two heat dissipation fins and the heat pipe passes through the positioning perforation along an extension axis. On a cross section perpendicular to the extension axis, a cross-sectional width of the heat pipe is D1 and a cross-sectional thickness of the heat pipe is D2, where D1 is greater than or equal to D2.

In order to achieve one, part, or all of the foregoing objectives or other objectives, an embodiment of the disclosure provides a projection device, which includes a case, a heat dissipation structure, and at least one heat source. The heat dissipation structure and the heat source are disposed in the case. The heat dissipation structure includes at least one heat dissipation fin set and at least one heat pipe. The heat dissipation fin set includes two heat dissipation fins, wherein each heat dissipation fin has a side edge and a positioning groove located at the side edge. The side edge of one of the at least two heat dissipation fins is joined to the side edge of another one of the at least two heat dissipation fins, and the positioning groove of one of the at least two heat dissipation fins is aligned with the positioning groove of another one of the at least two heat dissipation fins to form a positioning perforation. An end of the heat pipe is clamped between the at least two heat dissipation fins, and another end of the heat pipe is disposed at the heat source. The heat pipe passes through the positioning perforation along an extension axis. On a cross section perpendicular to the extension axis, a cross-sectional width of the heat pipe is D1 and a cross-sectional thickness of the heat pipe is D2, where D1 is greater than or equal to D2.

Based on the above, the embodiments of the disclosure have at least one of the following advantages or effects. In the heat dissipation structure according to the embodiments of the disclosure, the heat pipe is clamped and fixed between two heat dissipation fins. The heat dissipation fins do not need to be provided with grooves for filling a solder, so as to improve the contact area between the heat pipe and the two heat dissipation fins, such that the heat dissipation structure has a good heat dissipation efficiency. In the projection device according to the embodiments of the disclosure, the heat dissipation structure is integrated. Therefore, the heat generated by the heat source in the projection device can be quickly conducted to the outside through the heat dissipation structure.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a projection device according to an embodiment of the disclosure.

FIG. 2 is a front view of a fan and a heat dissipation structure of FIG. 1.

FIG. 3 is a front view of the heat dissipation structure of FIG. 1.

FIG. 4 is an exploded view of the heat dissipation structure of FIG. 3.

FIG. 5 is a perspective view of a heat dissipation fin of FIG. 4.

### DETAILED DESCRIPTION OF DISCLOSED EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

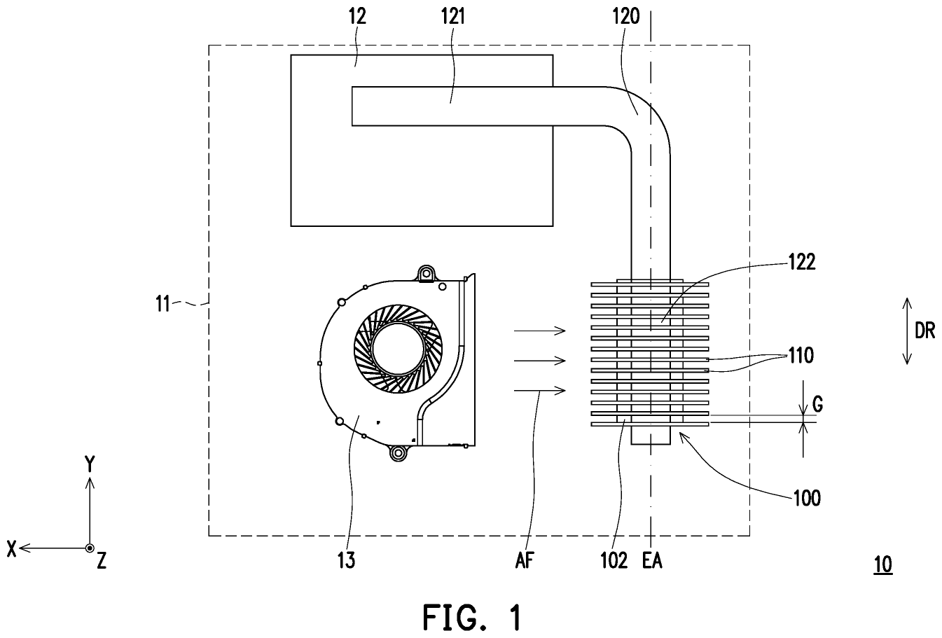

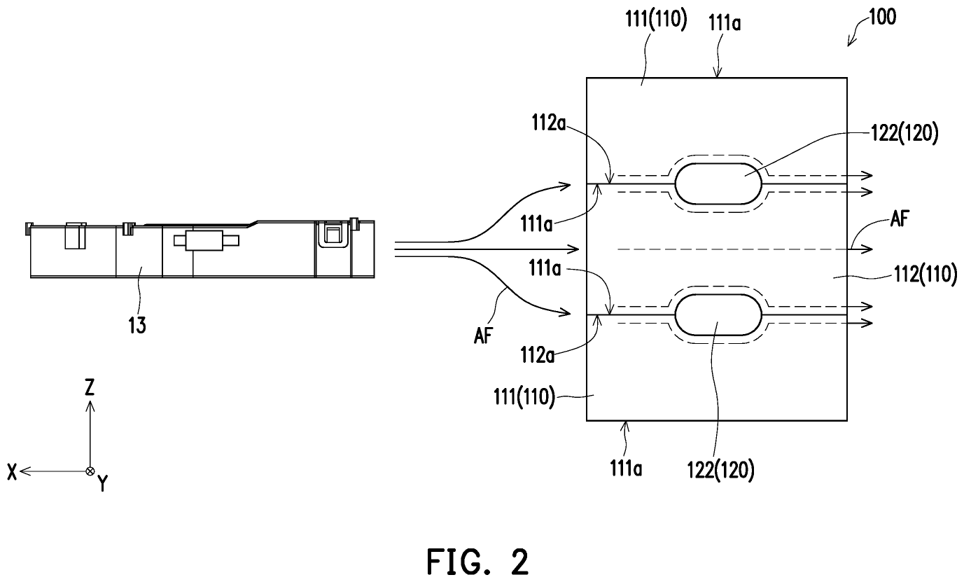

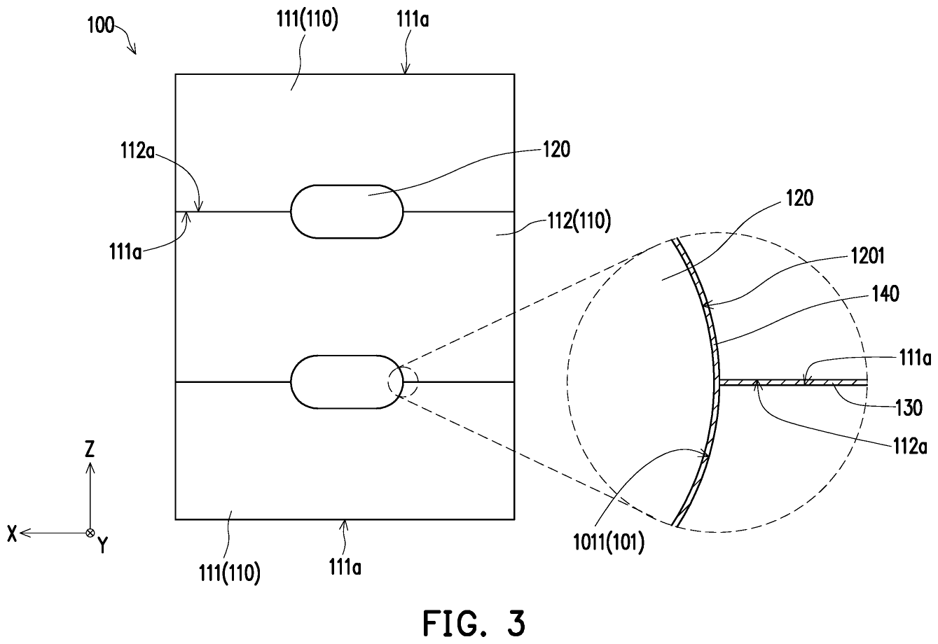

FIG. 1 is a top view of a projection device according to an embodiment of the disclosure. FIG. 2 is a front view of a fan and a heat dissipation structure of FIG. 1. FIG. 3 is a front view of the heat dissipation structure of FIG. 1. Please refer to FIG. 1 to FIG. 3. In the embodiment, a projection device 10 includes a case 11, a heat dissipation structure 100, and at least one heat source 12. The heat dissipation structure 100 is thermally coupled to the heat source 12, wherein the case 11 of FIG. 1 is illustrated using dashed lines to facilitate presentation of the configuration relationship between the heat dissipation structure 100 and the heat source 12 disposed in the case 11. For example, the heat source 12 may be a light source, a light valve, a projection lens, or a combination of the elements. When the projection device 10 is operating, the heat dissipation structure 100 conducts out the heat generated by the heat source 12.

Specifically, the heat dissipation structure 100 includes at least one heat dissipation fin set 110 and at least one heat pipe 120, wherein FIG. 1 schematically illustrates multiple heat dissipation fin sets 110 provided side by side along a direction DR, and a gap G is maintained between any two heat dissipation fin sets 110 in the direction DR. For example, each heat dissipation fin set 110 may include at least two heat dissipation fins, wherein FIG. 2 and FIG. 3 schematically illustrate three heat dissipation fins, which include two first heat dissipation fins 111 and one second heat dissipation fin 112. One of the two first heat dissipation fins 111, the second heat dissipation fin 112, and another one of the two first heat dissipation fins 111 are stacked along the z-axis in space, wherein the z-axis is perpendicular to the direction DR and the second heat dissipation fin 112 is clamped between the two first heat dissipation fins 111. FIG. 2 and FIG. 3 schematically illustrate two heat pipes 120, and any one of the first heat dissipation fins 111 and the second heat dissipation fin 112 clamp one heat pipe 120.

Each heat pipe 120 passes through the multiple heat dissipation fin sets 110, wherein each heat pipe 120 has a first end 121 and a second end 122. The first end 121 of each heat pipe 120 is disposed at the heat source 12 and the second end 122 of each heat pipe 120 is clamped between any one of the first heat dissipation fins 111 and the second heat dissipation fin 112. In other words, the first end 121 of each heat pipe 120 is thermally coupled to the heat source 12 and the second end 122 of each heat pipe 120 is thermally coupled to the multiple heat dissipation fin sets 110. The first end 121 of each heat pipe 120 may be in direct contact with the heat source 12 or connected to the heat source 12 through a suitable heat conduction element. Therefore, the heat generated by the heat source 12 is conducted to the multiple heat dissipation fin sets 110 through the heat pipe 120 and is conducted to the outside through the multiple heat dissipation fin sets 110. In the embodiment, the second end 122 of each heat pipe 120 passes through the multiple heat dissipation fin sets 110 along an extension axis EA, the extension axis EA is, for example, parallel to the direction DR, and the extension axis EA and the direction DR are substantially parallel to the y-axis in space. In other embodiments, the second end 122 of each heat pipe 120 extends through the multiple heat dissipation fin sets 110 along the extension axis EA, the extension axis EA of the second end 122 of each heat pipe 120 may have, for example, an acute angle with the direction DR, and the direction DR or the extension axis EA is substantially parallel to the y-axis in space.

In the embodiment, the projection device 10 further includes at least one fan 13, wherein the fan 13 is disposed in the case 11 and is disposed to be configured to generate an air flow AF towards the multiple heat dissipation fin sets 110 along the x-axis. Accordingly, the air flow AF performs heat exchange with the multiple heat dissipation fin sets 110 and performs heat exchange with the two heat pipes 120 to dissipate the heat conducted to the multiple heat dissipation fin sets 110 and the two heat pipes 120 out of the case 11, so as to prevent the operating temperature of the projection device 10 from becoming too high and disabled.

It should be noted that the number of the heat dissipation fins in each heat dissipation fin set 110 may be increased or decreased according to design requirements and the number of the heat pipe 120 may be increased or decreased according to design requirements or the number of the heat dissipation fins.

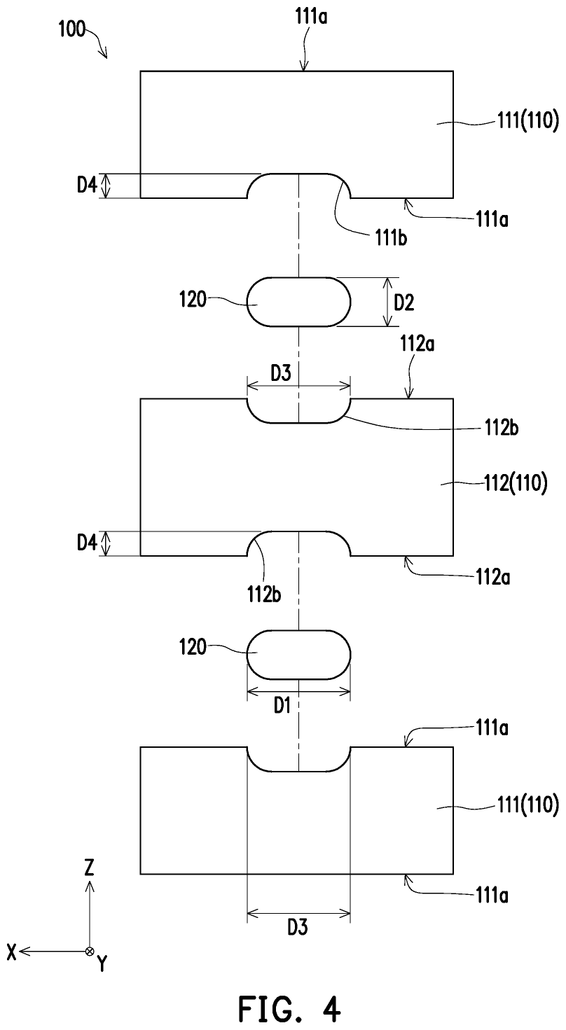

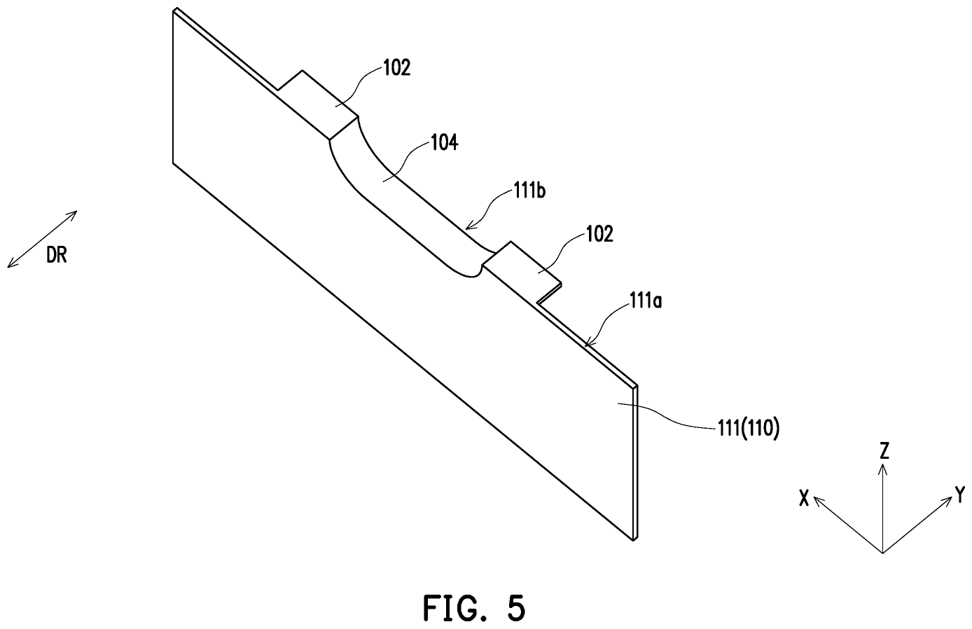

FIG. 4 is an exploded view of the heat dissipation structure of FIG. 3. FIG. 5 is a perspective view of a heat dissipation fin of FIG. 4. Please refer to FIG. 2 to FIG. 4. In the embodiment, in terms of any one of the heat dissipation fin sets 110, any one of the first heat dissipation fins 111 has a positioning groove 111b and two opposite side edges 111a, and the positioning groove 111b is located at (or recessed in) one of the side edges 111a of the corresponding first heat dissipation fin 111. On the other hand, the second heat dissipation fin 112 has two positioning grooves 112b and two opposite side edges 112a, and the two positioning grooves 112b are respectively located at (or recessed in) the two side edges 112a of the second heat dissipation fin 112.

In other embodiments, the number of the positioning groove on any one of the side edges of each heat dissipation fin may be increased according to design requirements or the number of the heat pipe.

In the embodiment, each side edge 112a of the second heat dissipation fin 112 is joined to the side edge 111a having the positioning groove 111b in any one of the first heat dissipation fins 111, and the positioning groove 112b is aligned with the positioning groove 111b to form a positioning perforation 101. The second end of one of the two heat pipes 120 is clamped between the second heat dissipation fin 112 and one of the first heat dissipation fins 111, and the second end of another one of the two heat pipes 120 is clamped between the second heat dissipation fin 112 and another one of the first heat dissipation fins 111. As shown in FIG. 1 and FIG. 3, the second end 122 of the heat pipe 120 passes through the positioning perforations 101 of the heat dissipation fin set 110 along the extension axis EA (i.e. the direction DR), and the extension axis EA (i.e. the direction DR) is perpendicular to the second heat dissipation fin 112 and the two first heat dissipation fins 111 in each heat dissipation fin set 110. For example, the extension axis EA (i.e. the direction DR) is perpendicular to an extension direction of the side edge 111a of each first heat dissipation fin 111 and the side edge 112a of the second heat dissipation fin 112.

The perspectives of FIG. 3 and FIG. 4 are perpendicular to the direction DR in FIG. 1, and each heat pipe 120 may be a flat pipe. In the embodiment where the extension axis EA of the heat pipe 120 is parallel to the direction DR, on a cross section perpendicular to the direction DR (i.e. the extension axis EA), the cross-sectional width of each heat pipe 120 is D1 and the cross-sectional thickness of each heat pipe 120 is D2, where the cross-sectional width D1 is greater than the cross-sectional thickness D2. On the other hand, the cross-sectional width D1 of each heat pipe 120 is parallel to the side edges 112a of the second heat dissipation fin 112 and the side edges 111a of any one of the first heat dissipation fins 111, and is parallel to the x-axis.

The cross-sectional thickness D2 of each heat pipe 120 is perpendicular to the side edges 112a of the second heat dissipation fin 112 and the side edges 111a of any one of the first heat dissipation fins 111, and is parallel to the z-axis. As shown in FIG. 2 to FIG. 4, the flow direction of the air flow AF flowing through the heat pipe 120 is substantially parallel to the cross-sectional width D1 of each heat pipe 120. According to this design, the flow resistance of the air flow AF flowing through the heat pipe 120 may be reduced, so as to accelerate the flow efficiency of the air flow AF and improve the heat exchange efficiency.

In other embodiments, each heat pipe may be a round pipe or an oval pipe. Taking each heat pipe as the round pipe as an example, the cross-sectional width of each heat pipe is equal to the cross-sectional thickness.

In the embodiment, the outer contour of each heat pipe 120 matches the inner contour of each positioning perforation 101 of the corresponding heat dissipation fin set 110, and the ratio of the outer circumference of each heat pipe 120 to the inner circumference of the corresponding positioning perforation 101 is between 0.93 and 1, so as to increase the contact area and the heat conduction area between any one of the first heat dissipation fins 111 and the second heat dissipation fin 112 and the corresponding heat pipe 120, such that the heat dissipation structure 100 has a good heat dissipation efficiency.

In terms of any one of the first heat dissipation fins 111 and the second heat dissipation fin 112 joined to each other, the geometrical contour of the positioning groove 111b is the same as the geometrical contour of the corresponding positioning groove 112b, and the same are symmetrically provided up and down. The perspectives of FIG. 3 and FIG. 4 are perpendicular to the direction DR in FIG. 1. On a cross section perpendicular to the direction DR, the cross-sectional widths of the positioning groove 111b and the positioning groove 112 b are both D3, and cross-sectional depths of the positioning groove 111b and the positioning groove 112b are both D4. The cross-sectional width D3 is parallel to the side edges 112a of the second heat dissipation fin 112 and the side edges 111a of any one of the first heat dissipation fins 111, and is parallel to the x-axis. The cross-sectional depth D4 is perpendicular to the side edges 112a of the second heat dissipation fin 112 and the side edges 111a of any one of the first heat dissipation fins 111, and is parallel to the z-axis.

Among the matched and aligned positioning groove 111b of any one of the first heat dissipation fins 111 and positioning groove 112b of the second heat dissipation fin 112, the positioning groove 111b is configured to accommodate a part of the heat pipe 120 and the positioning groove 112b is configured to accommodate another part of the heat pipe 120. Specifically, the cross-sectional width D1 of the heat pipe 120 is parallel to the cross-sectional widths D3 of the positioning groove 111b and the positioning groove 112b, and the cross-sectional width D3 and the cross-sectional width D1 satisfy the following relationship: D3≥(D1+0.1) mm. On the other hand, the cross-sectional thickness D2 of the heat pipe 120 is parallel to the cross-sectional depths D4 of the positioning groove 111b and the positioning groove 112b, and the cross-sectional depth D4 and the cross-sectional thickness D2 satisfy the following relationship: D4≥(D2/2+0.05) mm.

The above geometrical parameter design can ensure that the positioning perforation 101 formed by the matched and aligned positioning groove 111b and positioning groove 112b completely installs the heat pipe 120 therein, and accommodates the solder configured to join the heat pipe 120 to any one of the first heat dissipation fins 111 and the solder configured to join the heat pipe 120 to the second heat dissipation fin 112.

Please refer to FIG. 3, the side edge 111a of any one of the first heat dissipation fins 111 and the side edge 112a of the second heat dissipation fin 112 are joined and fixed to each other through a soldering layer 130, so as to clamp and fix the heat pipe 120 therebetween. In other words, the soldering layer 130 is provided between the side edge 111a of any one of the first heat dissipation fins 111 and the side edge 112a of the second heat dissipation fin 112. On the other hand, an outer wall surface 1201 of each heat pipe 120 and an inner wall surface 1011 of the corresponding positioning perforation 101 are joined and fixed to each other through the soldering layer 140, so as to prevent each heat pipe 120 from randomly sliding within the corresponding positioning perforation 101. In other words, the soldering layer 140 is provided between the outer wall surface 1201 of each heat pipe 120 and the inner wall surface 1011 of the corresponding positioning perforation 101. In other embodiments, when the soldering layer 140 is provided between the outer wall surface 1201 of each heat pipe 120 and the inner wall surface 1011 of the corresponding positioning perforation 101, then any one of the first heat dissipation fins 111 and the second heat dissipation fin 112 may be fixed to each other through the soldering layer 140, and the side edge 111a of any one of the first heat dissipation fins 111 and the side edge 112a of the second heat dissipation fin 112 may be fixed in position by clamping the heat pipe without the soldering layer 130.

Please refer to FIG. 1, FIG. 2, and FIG. 5. In each heat dissipation fin set 110, each first heat dissipation fin 111 is provided with two heat dissipation branches 102, wherein the two heat dissipation branches 102 are connected to the side edge 111a of the first heat dissipation fin 111 and protrude along the direction DR. In two adjacent heat dissipation fin sets 110, the two heat dissipation branches 102 belonging to any one of the first heat dissipation fins 111 of one of the heat dissipation fin sets 110 extend towards another heat dissipation fin set 110 and are located within the gap G. Each first heat dissipation fin 111 is further provided with a heat dissipation protruding portion 104. The heat dissipation protruding portion 104 extends from the positioning groove 111b towards another heat dissipation fin set 110 along the direction DR and is located in the gap G. Two ends of the heat dissipation protruding portion 104 may be respectively connected to the two heat dissipation branches 102. For example, the heat conducted to the first heat dissipation fin 111 through the heat pipe 120 may be further conducted to the two heat dissipation branches 102 through the heat dissipation protruding portion 104. When the air flow AF flows through the two heat dissipation branches 102 and the heat dissipation protruding portion 104, the air flow AF performs heat exchange with the two heat dissipation branches 102 and the heat dissipation protruding portion 104 to dissipate the heat conducted to the two heat dissipation branches 102 and the heat dissipation protruding portion 104 out of the case 11. In other words, the two heat dissipation branches 102 and the heat dissipation protruding portion 104 help to increase the heat exchange area of the first heat dissipation fin 111.

On the other hand, the flow direction of the air flow AF is substantially parallel to the two heat dissipation branches 102 and the heat dissipation protruding portion 104. According to this design, the flow resistance of the air flow AF flowing through the two heat dissipation branches 102 and the heat dissipation protruding portion 104 is reduced to accelerate the flow efficiency of the air flow AF and improve the heat exchange efficiency. In addition, the two heat dissipation branches 102 are respectively located on two sides of the positioning groove 111b and are adjacent to the periphery of the positioning groove 111b. According to this design, the heat conduction path between any one of the heat dissipation branches 102 and the heat pipe 120 may be increased to improve the heat conduction efficiency. In addition, in other embodiments, the two heat dissipating branches 102 and the heat dissipation protruding portion 104 may be a structure integrally formed from the same plate, for example, made by bending a heat dissipation fin. The two heat dissipation branches 102 and the heat dissipation protruding portion 104 may also be respectively structures of separate plates, which are connected to one another after being formed separately, but the disclosure is not limited thereto.

In other embodiments, the number of the heat dissipation branch on the first heat dissipation fin may be increased or decreased according to design requirements. Alternatively, any one of the two side edges of the second heat dissipation fin is provided with at least one heat dissipation branch. Also, alternatively, one of the first heat dissipation fin and the second heat dissipation fin is selected to provide the heat dissipation branch, or both the first heat dissipation fin and the second heat dissipation fin are provided with the heat dissipation branches.

In summary, the embodiments of the disclosure have at least one of the following advantages or effects. In the heat dissipation structure according to the embodiments of the disclosure, the heat pipe is clamped and fixed between two heat dissipation fins, so as to increase the contact area between the heat pipe and the two heat dissipation fins, such that the heat dissipation structure has a good heat dissipation efficiency. On the other hand, the heat dissipation fin is provided with the heat dissipation branch and the heat dissipation protruding portions which are connected to the side edge thereof and protrude along the extension axis, so as to increase the heat exchange area. In the projection device according to the embodiments of the disclosure, the heat dissipation structure is integrated. Therefore, the heat generated by the heat source in the projection device can be quickly conducted to the outside through the heat dissipation structure. On the other hand, on the cross section perpendicular to the extension axis, the cross-sectional width of the heat pipe is greater than or equal to the cross-sectional thickness of the heat pipe and the flow direction of the air flow generated by the fan in the projection device is substantially parallel to the cross-sectional width of the heat pipe. Accordingly, the flow resistance of the air flow flowing through the heat pipe may be reduced so as to accelerate the flow efficiency of the air flow and improve the heat exchange efficiency.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A heat dissipation structure, comprising at least one heat dissipation fin set and at least one heat pipe, wherein:
the at least one heat dissipation fin set comprises at least two heat dissipation fins, wherein each of the at least two heat dissipation fins has a side edge and a positioning groove located at the side edge, the side edge of one of the at least two heat dissipation fins is joined to the side edge of another one of the at least two heat dissipation fins, and the positioning groove of one of the at least two heat dissipation fins is aligned with the positioning groove of another one of the at least two heat dissipation fins to form a positioning perforation; and
the at least one heat pipe is clamped between the at least two heat dissipation fins and the at least one heat pipe passes through the positioning perforation along an extension axis, wherein
on a cross section perpendicular to the extension axis, a cross-sectional width of the at least one heat pipe is D1 and a cross-sectional thickness of the at least one heat pipe is D2, where D1 is greater than or equal to D2.

2. The heat dissipation structure according to claim 1, wherein the extension axis is perpendicular to any one of the at least two heat dissipation fins, the cross-sectional width of the at least one heat pipe is parallel to the side edge of any one of the at least two heat dissipation fins, and the cross-sectional thickness of the at least one heat pipe is perpendicular to the side edge of any one of the at least two heat dissipation fins.

3. The heat dissipation structure according to claim 1, wherein on a cross section perpendicular to the extension axis, a cross-sectional width of the positioning groove of any one of the at least two heat dissipation fins is D3 and a cross-sectional depth of the positioning groove of any one of the at least two heat dissipation fins is D4, where D3 is greater than D4.

4. The heat dissipation structure according to claim 3, wherein the cross-sectional width of the positioning groove of any one of the at least two heat dissipation fins is parallel to the side edge of any one of the at least two heat dissipation fins, and the cross-sectional depth of the positioning groove of any one of the at least two heat dissipation fins is perpendicular to the side edge of any one of the at least two heat dissipation fins.

5. The heat dissipation structure according to claim 3, wherein D3≥(D1+0.1) mm and D4≥(D2/2+0.05) mm.

6. The heat dissipation structure according to claim 1, wherein a ratio of an outer circumference of the at least one heat pipe to an inner circumference of the positioning perforation is between 0.93 and 1.

7. The heat dissipation structure according to claim 1, wherein at least one of the at least two heat dissipation fins is provided with at least one heat dissipation branch connected to the side edge and protruding along the extension axis.

8. The heat dissipation structure according to claim 7, wherein the at least one heat dissipation branch is connected to a periphery of the positioning groove.

9. The heat dissipation structure according to claim 7, wherein at least one of the at least two heat dissipation fins is provided with a heat dissipation protruding portion, the heat dissipation protruding portion protrudes from the positioning groove along the extension axis, and the heat dissipation protruding portion is connected to the at least one heat dissipation branch.

10. The heat dissipation structure according to claim 1, wherein the at least one heat dissipation fin set further comprises a soldering layer, located between an outer wall surface of the at least one heat pipe and an inner wall surface of the positioning perforation.

11. The heat dissipation structure according to claim 1, wherein the at least one heat dissipation fin set further comprises a soldering layer, located between the side edge of one of the at least two heat dissipation fins and the side edge of another one of the at least two heat dissipation fins.

12. The heat dissipation structure according to claim 1, wherein a number of the at least one heat dissipation fin set is plural and the plurality of heat dissipation fin sets are provided side by side along the extension axis.

13. A projection device, comprising a case, a heat dissipation structure, and at least one heat source, wherein the heat dissipation structure and the at least one heat source are disposed in the case, and the heat dissipation structure comprises at least one heat dissipation fin set and at least one heat pipe, wherein:
the at least one heat dissipation fin set comprises at least two heat dissipation fins, wherein each of the at least two heat dissipation fins has a side edge and a positioning groove located at the side edge, the side edge of one of the at least two heat dissipation fins is joined to the side edge of another one of the at least two heat dissipation fins, and the positioning groove of one of the at least two heat dissipation fins is aligned with the positioning groove of another one of the at least two heat dissipation fins to form a positioning perforation; and
an end of the at least one heat pipe is clamped between the at least two heat dissipation fins, another end of the at least one heat pipe is disposed at the at least one heat source, and the end of the at least one heat pipe passes through the positioning perforation along an extension axis, wherein
on a cross section perpendicular to the extension axis, a cross-sectional width of the at least one heat pipe is D1 and a cross-sectional thickness of the at least one heat pipe is D2, where D1 is greater than or equal to D2.

14. The projection device according to claim 13, wherein the projection device further comprises at least one fan and the at least one fan is disposed in the case.

15. The projection device according to claim 13, wherein the extension axis is perpendicular to any one of the at least two heat dissipation fins.

16. The projection device according to claim 13, wherein at least one of the at least two heat dissipation fins is provided with at least one heat dissipation branch connected to the side edge and protruding along the extension axis.

17. The projection device according to claim 16, wherein the at least one heat dissipation branch is connected to a periphery of the positioning groove.

18. The projection device according to claim 16, wherein at least one of the at least two heat dissipation fins is provided with a heat dissipation protruding portion, the heat dissipation protruding portion protrudes from the positioning groove along the extension axis, and the heat dissipation protruding portion is connected to the at least one heat dissipation branch.

19. The projection device according to claim 13, wherein a number of the at least one heat dissipation fin set is plural and the plurality of heat dissipation fin sets are provided side by side along the extension axis.
